(19) United States
(12) Patent Application Publication
(10) Pub. No.: US 2007/0249090 A1
(43) Pub. Date: Oct. 25, 2007

(54) Phase-change memory cell adapted to prevent over-etching or under-etching

(76) Inventors: Jan Boris Philipp, Peekskill, NY (US); Chia Hua Ho, Tarrytown, NY (US); Brandon Yee, Westbury, NY (US)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/410,262

(22) Filed: Apr. 24, 2006

(51) Int. Cl. H01L 21/06

(52) U.S. Cl. 438/102

(57) ABSTRACT

A memory cell includes a first electrode and a second electrode. The second electrode has a first layer and a second layer. The first layer has a lower etch rate relative to the second layer. The memory cell includes a phase-change material positioned between the first electrode and the second electrode.

### BACKGROUND

Phase-change memories include phase-change materials that exhibit at least two different states. Phase-change material may be used in memory cells to store bits of data. The states of phase-change material may be referenced to as amorphous and crystalline states. The states may be distinguished because the amorphous state generally exhibits higher resistivity than does the crystalline state. Generally, the amorphous state involves a more disordered atomic structure, while the crystalline state is an ordered lattice. Some phase-change materials exhibit two crystalline states, e.g., a face-centered cubic (FCC) state and a hexagonal closest packing (HCP) state. These two crystalline states have different resistivities and may be used to store bits of data. In the following description, the amorphous state generally refers to the state having the higher resistivity, and the crystalline state generally refers to the state having the lower resistivity.

Phase change in the phase-change materials may be induced reversibly. In this way, the memory may change from the amorphous state to the crystalline state, and from the crystalline state to the amorphous state, in response to temperature changes. The temperature changes to the phase-change material may be achieved in a variety of ways. For example, a laser can be directed to the phase-change material, current may be driven through the phase-change material, or current can be fed through a resistive heater adjacent the phase-change material. With any of these methods, controllable heating of the phase-change material causes controllable phase change within the phase-change material.

Typical fabrication of a phase-change memory cell having a pillar cell structure involves an etching process. This etching process is difficult to control and the etch rate varies across the wafer area. A known pillar cell structure includes a bottom electrode, phase-change material, and a top electrode. The top electrode of the phase-change memory cell is not homogenous, which contributes to uneven etching over the wafer. In addition, the etch rate for phase-change material may be higher than the etch rate for the top electrode material. This results in the etch process being stopped too early or too late. Consequently, the pillar cell is not uniform and tends to become structurally unstable.

For these and other reasons, there is a need for the present invention.

### SUMMARY

One embodiment of the present invention provides a memory cell. The memory cell includes a first electrode and a second electrode. The second electrode has a first layer and a second layer. The first layer has a lower etch rate relative to the second layer. The memory cell includes a phase-change material positioned between the first electrode and the second electrode.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a block diagram illustrating one embodiment of a memory device.

FIG. 2 illustrates a cross-sectional view of one embodiment of a phase-change memory cell.

FIG. 3 illustrates a cross-sectional view of one embodiment of a partially fabricated phase-change memory cell including a preprocessed wafer.

FIG. 4 illustrates a cross-sectional view of one embodiment of a partially fabricated phase-change memory cell including the preprocessed wafer and a phase-change material layer.

FIG. 5 illustrates a cross-sectional view of one embodiment of a partially fabricated phase-change memory cell including the preprocessed wafer, the phase-change material layer, and a first layer of a top electrode.

FIG. 6 illustrates a cross-sectional view of one embodiment of a partially fabricated phase-change memory cell including the preprocessed wafer, the phase-change material layer, and a dual-layer top electrode.

FIG. 7 illustrates a cross-sectional view of one embodiment of a partially fabricated phase-change memory cell including the preprocessed wafer, the phase-change material layer, the dual-layer top electrode, and a mask layer provided for enabling an etching process.

FIG. 8 illustrates a cross-sectional view of one embodiment of a partially fabricated phase-change memory cell including the preprocessed wafer, the phase-change material layer, and the dual-layer top electrode after the completion of a first etch process.

FIG. 9 illustrates a cross-sectional view of one embodiment of a partially fabricated phase-change memory cell including the preprocessed wafer, the phase-change material layer, and the dual-layer electrode after the completion of a second etch process.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

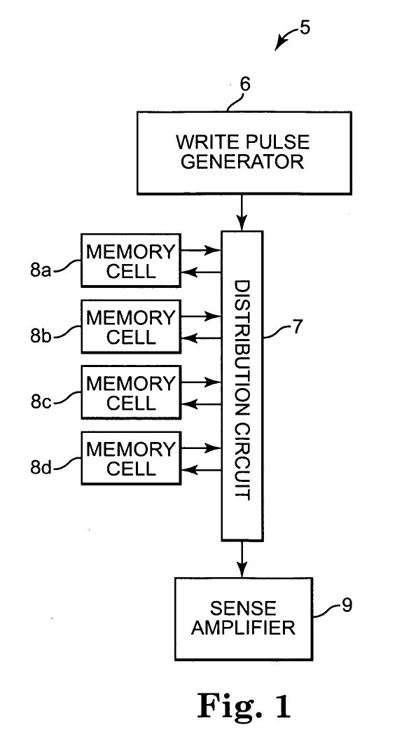

FIG. 1 is a block diagram illustrating one embodiment of a memory device 5. Memory device 5 includes a write pulse generator 6, a distribution circuit 7, memory cells 8a, 8b, 8c, and 8d, and a sense amplifier 9. In one embodiment, memory cells 8a-8d are phase-change memory cells that are based on the amorphous to crystalline phase transition of the memory material.

In one embodiment, write pulse generator 6 generates current or voltage pulses that are controllably directed to memory cells 8a-8d via distribution circuit 7. In one embodiment, distribution circuit 7 includes a plurality of transistors that controllably direct current or voltage pulses to the memory cells. In one embodiment, memory cells 8a-8d are made of a phase-change material that may be changed from an amorphous state to a crystalline state or from a crystalline state to an amorphous state under the influence of temperature change. The degree of crystallinity thereby defines at least two memory states for storing data within memory device 5. The at least two memory states can be assigned to the bit values “0” and “1”. The bit states of memory cells 8a-8d differ significantly in their electrical resistivity. In the amorphous state, a phase-change material exhibits significantly higher resistivity than in the crystalline state. In this way, sense amplifier 9 reads the cell resistance such that the bit value assigned to a particular memory cell 8a-8d is determined.

To program a memory cell 8a-8d within memory device 5, write pulse generator 6 generates a current or voltage pulse for heating the phase-change material in the target memory cell. In one embodiment, write pulse generator 6 generates an appropriate current or voltage pulse, which is fed into distribution circuit 7 and distributed to the appropriate target memory cell 8a-8d. The current or voltage pulse amplitude and duration is controlled depending on whether the memory cell is being set or reset. Generally, a “set” operation of a memory cell is heating the phase-change material of the target memory cell above its crystalline temperature (but below its melting temperature) long enough to achieve the crystalline state. Generally a “reset” operation of a memory cell is heating the phase-change material of the target memory cell above its melting temperature, and then quickly quench cooling the material, thereby achieving the amorphous state.

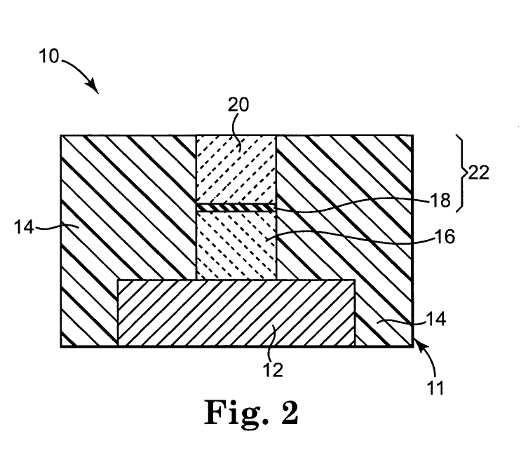

FIGS. 2-9 illustrate[s] cross-sectional views of one embodiment of a phase-change memory cell 10 at various stages of fabrication. In particular, FIG. 2 illustrates a cross-sectional view through a phase-change memory cell 10 after completion of the fabrication process in accordance with one embodiment of the present invention. Phase-change memory cell 10 includes a preprocessed wafer 11 having a bottom electrode or first electrode 12, a phase-change material layer 16, a top electrode or second electrode 22 having a first layer 18 and a second layer 20, and insulation material 14. In one embodiment, phase-change material layer 16 is laterally enclosed (e.g., completely enclosed) by insulation material 14, which defines the current path and hence the location of the phase-change region in phase-change material layer 16.

In one embodiment, phase-change material layer 16 is located between preprocessed wafer 11 and top electrode 22. In another embodiment, phase-change material layer 16 is located between top electrode 22 and a SiN layer (not shown) deposited on preprocessed wafer 11. The SiN layer has a thickness less than the thickness of the phase-change material layer. In one embodiment, phase-change material layer 16 is a combination of phase-change materials. Phase-change material layer 16 provides a storage location for storing one bit or several bits of data.

Phase-change material layer 16 may be made up of a variety of materials in accordance with the present invention. Generally, chalcogenide alloys that contain one or more elements from Group VI of the periodic table are useful as such materials. In one embodiment, phase-change material layer 16 of memory cell 10 is made up of a chalcogenide compound material, such as GeSbTe, SbTe, GeTe, or AgInSbTe. In another embodiment, the phase-change material is chalcogen free, such as GeSb, GaSb, InSb, or GeGaInSb. In other embodiments, the phase-change material is made up of any suitable material including one or more of the elements Ge, Sb, Te, Ga, As, In, Se, and S.

Insulation material 14 can be any suitable insulator, such as SiN, SiO₂, fluorinated silica glass (FSG), boro-phosphorous silicate glass (BPSG), or a low-k material. First layer 18 of top electrode 22 is made up of tungsten or a metal nitride material, such as tantalum nitride, titanium nitride, titanium silicon nitride, titanium aluminum nitride, tungsten nitride, titanium tungsten nitride, or another material suitable for functioning as an etch-stop material. Second layer 20 of top electrode 22 can be any suitable electrode material, such as TiN, TaN, W, Al, or Cu. In one embodiment, first layer 18 is TiN and second layer 20 is W. In another embodiment, first layer 18 is TiN and second layer 20 is Al. In another embodiment, first layer 18 is TaN and second layer 20 is W. In another embodiment, first layer 18 is TaN and second layer 20 is Al. In another embodiment, first layer 18 is W and second layer 20 is Al. In other embodiments, other suitable combinations are used.

In one embodiment, during the fabrication process, first layer 18 of top electrode 22 performs an etch-stop function. As a result, the first layer 18 controls the etching process and prevents the etching process from being stopped too early or too late. First layer 18 is made of material that has a lower etching rate compared to the material of second layer 20. Additionally, first layer 18 has a smaller thickness relative to second layer 20.

The complete etching process includes two etches. During the first etch, second layer 20 of top electrode 22 is etched until first layer 18 begins to be etched. At this point, the first etch is stopped and a second etch is initiated to adequately match a suitable etching rate for phase-change material layer 16. Consequently, under-etching or over-etching of phase-change material layer 16 in memory cell 10 is prevented.

In operation, during a set operation of phase-change memory cell 10, a set current or voltage pulse is selectively enabled to bottom electrode 12 and sent through phase-change material 16 thereby heating it above its crystallization temperature (but usually below its melting temperature). In this way, phase-change material 16 reaches its crystalline state during the set operation. During a reset operation of phase-change memory cell 10, a reset current and/or voltage pulse is selectively enabled to bottom electrode 12 and sent through phase-change change material 16. The reset current or voltage quickly heats phase-change material 16 above its melting temperature. After the current and/or voltage pulse is turned off, phase-change material 16 quickly quench cools into the amorphous state.

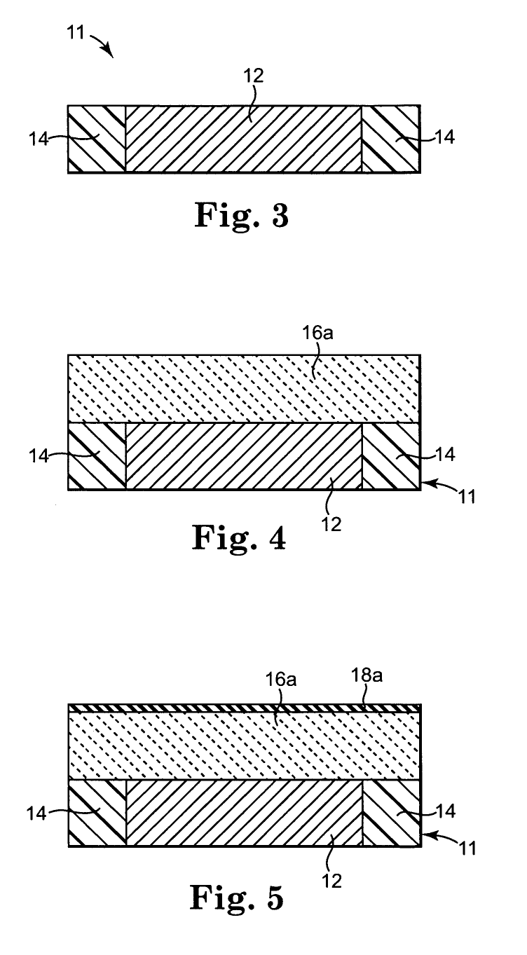

FIG. 3 illustrates a cross-sectional view of one embodiment of a partially fabricated phase-change memory cell 10 including a preprocessed wafer 11. Preprocessed wafer 11 includes bottom electrode or first electrode 12 surrounded by insulation material 14. In one embodiment, preprocessed wafer 11 includes active devices such as transistors or diodes (not illustrated). In one embodiment, preprocessed wafer 11 includes a field effect transistor (FET). In one embodiment, preprocessed wafer 11 includes a substrate including a selection device (not illustrated), first electrode 12, and insulation material 14. In one embodiment, first electrode 12 is a tungsten plug, copper plug, or other suitable electrode. Insulation material 14 is SiN, SiO₂, FSG, BPSG, or other suitable dielectric material. In one embodiment, the selection device included in preprocessed wafer 11 is a transistor.

FIG. 4 illustrates a subsequent process in the fabrication of phase-change memory cell 10. In particular, FIG. 4 illustrates a cross-sectional view of one embodiment of a partially fabricated phase-change memory cell 10 including preprocessed wafer 11 and a phase-change material layer 16a. In one embodiment, phase-change material layer 16a is deposited as a planar film using known deposition methods, such as chemical vapor deposition (CVD), atomic layer deposition (ALD), metal organic chemical vapor deposition (MOCVD), plasma vapor deposition (PVD), jet vapor deposition (JVP), or other suitable deposition technique.

In one embodiment, the thickness of phase-change material layer 16a is on the order of approximately 10-100 nanometers. In other embodiments, the thickness of phase-change material layer 16a is on the order of approximately 20-60 nanometers. Phase-change material layer 16a may be made up of a variety of materials in accordance with the present invention.

FIG. 5 illustrates a subsequent process in the fabrication of phase-change memory cell 10. In particular, FIG. 5 illustrates a cross-sectional view through one embodiment of a partially fabricated phase-change memory cell 10 including preprocessed wafer 11, phase-change material layer 16a, and a first layer 18a of top electrode 22. First layer 18a functions as an etch-stop layer. In one embodiment, first layer 18a is made up of a material suitable for performing an etch stop function, as previously disclosed herein. In one embodiment, first layer 18a is deposited as a planar film using known deposition methods such as CVD, ALD, MOCVD, PVD, JVP, or other suitable deposition technique. Etch-stop layer 18a has a lower etching rate compared to layer 20 (illustrated in FIG. 2). In one embodiment, etch-stop layer 18a is made of TiN. In other embodiments, etch-stop layer 18a is made of TiN, TaN, W, or another suitable material. Having an etch-stop layer enables a uniform etching process through phase-change material layer 16a during fabrication of phase-change memory cell 10.

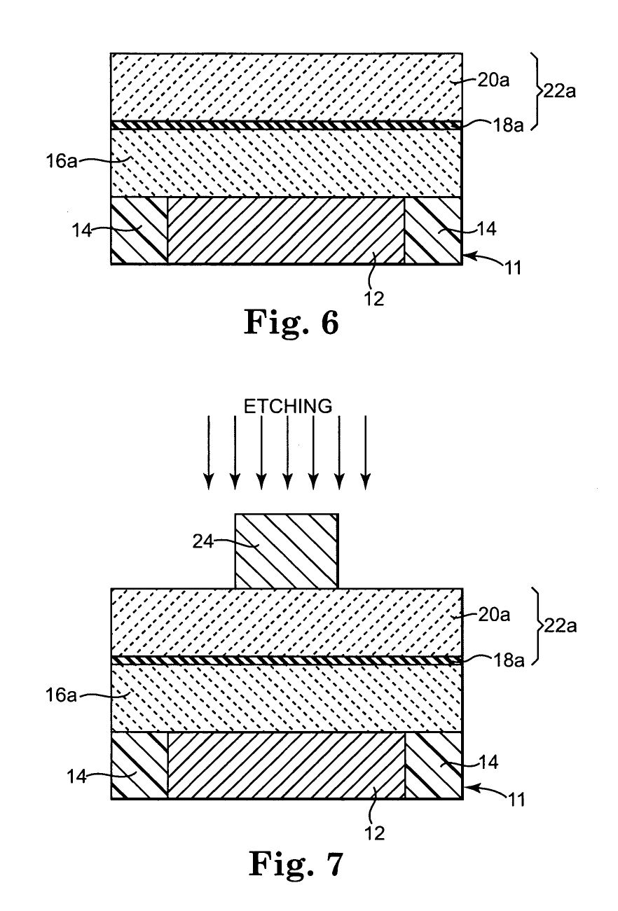

FIG. 6 illustrates a subsequent process in the fabrication of phase-change memory cell 10. In particular, FIG. 6 illustrates a cross-sectional view of one embodiment of a partially fabricated phase-change memory cell 10 including preprocessed wafer 11, phase-change material layer 16a, first layer 18a and second layer 20a. First layer 18a in combination with second layer 20a provides a top electrode 22a. Second layer 20a is made up of a variety of materials in accordance with the present invention, and has a higher etching rate compared to first layer 18a. In one embodiment, second layer 20a is made of W. In other embodiments, second layer 20 is made of Al or another suitable material.

Typical phase-change memory cells have a single layer top electrode. This single layer top electrode when deposited over the phase-change material layer may have uneven thickness across the lateral surface of the memory cell. During the etching process in the fabrication of a memory cell, uneven thickness of a single layer top electrode contributes to over-etching or under-etching of the phase-change material layer. The phase-change material has a higher etch rate when compared to the material of the top electrode, further contributing to over-etching of the phase-change material layer. The resulting pillar may become unstable due to the over-etching of the phase-change material layer.

Using a dual-layer top electrode 22a in place of a single layer top electrode prevents the forming of an unstable pillar. The dual-layer top electrode 22a reduces uneven etching of phase-change material layer 16a during the fabrication of phase-change memory cell 10. First layer 18a of top electrode 22a performs an etch-stop function and has a thickness substantially smaller than the total thickness of top electrode 22a.

FIG. 7 illustrates a subsequent process in the fabrication of phase-change memory cell 10. In particular, FIG. 7 illustrates a cross-sectional view of one embodiment of a partially fabricated phase-change memory cell 10 including preprocessed wafer 11, phase-change material layer 16a, dual-layer top electrode 22a, and a mask layer 24 provided for enabling an etching process. During an etching process, mask layer 24 masks a portion of second layer 20a of top electrode 22a. In one embodiment, mask layer 24 comprises a photoresist material. The photoresist material is applied in a layer over second layer 20a using a lithography process. All areas but the mask area are washed away to form mask layer 24. In another embodiment, mask layer 24 is a hard mask.

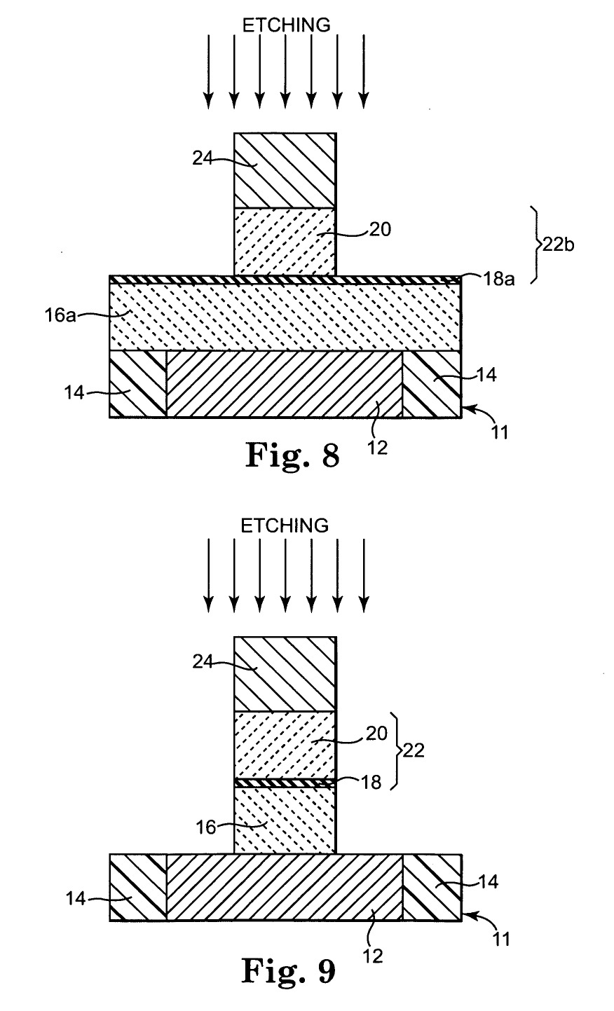

FIG. 8 illustrates a further process in the fabrication of phase-change memory cell 10. In particular, FIG. 8 illustrates a cross-sectional view of one embodiment of a partially fabricated phase-change memory cell 10 including preprocessed wafer 11, phase-change material layer 16a, and dual-layer top electrode 22b after the completion of a first etch process. Exposed portions of second layer 20a of dual-layer top electrode 22a are etched to form layer 20 and expose portions of first layer 18a of top electrode 22a.

The first etch is stopped after the etching process has etched through second layer 20a and reaches first layer 18a. After the first etch, a second layer 20 of top electrode 22b is formed that mirrors the footprint of mask layer 24. Since first layer 18a is a thin layer relative to the thickness of top electrode 22, the thickness variations in first layer 18a are minimal in comparison to a situation where the electrode has a significantly thicker layer. In one embodiment, the material of first layer 18a has a slower etch rate compared to the material of second layer 20. In one embodiment, the material of first layer 18a has a slower etch rate compared to phase-change material layer 16a.

FIG. 9 illustrates a subsequent process in the fabrication of phase-change memory cell 10. In particular, FIG. 9 illustrates a cross-sectional view of one embodiment of a partially fabricated phase-change memory cell 10 including preprocessed wafer 11, phase-change material layer 16, first layer 18 of top electrode 22, second layer 20 of top electrode 22, and mask layer 24 after the completion of a second etch process. A second etch process is performed to expose preprocessed wafer 11.

In one embodiment, upon completion of the second etch the mask layer is removed and insulation material is deposited over exposed portions of top electrode 22, phase-change material layer 16, and preprocessed wafer 11. The insulation material is planarized using chemical mechanical planarization (CMP) or another suitable planarization technique to form phase-change memory cell 10 as illustrated in FIG. 2. In another embodiment, where the mask layer is a hard mask, the insulation material is deposited over exposed portions of mask layer 24, top electrode 22, phase-change material layer 16, and preprocessed wafer 11. The insulation material is planarized using chemical mechanical planarization (CMP) or another suitable planarization technique to form phase-change memory cell 10 as illustrated in FIG. 2.

Embodiments of the present invention provide a phase-change memory cell having a dual-layer top electrode. The dual-layer top electrode enables the control of an etching process during the fabrication of the phase-change memory cell. One of the layers of the dual-layer top electrode performs the function of an etch-stop layer thereby enabling uniform etching of the phase-change material during an etching process. The thickness of the etch-stop layer is significantly smaller than the over-all thickness of the top electrode.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A memory cell comprising:
a first electrode;
a second electrode having a first layer and a second layer, the first layer made of an etch-stop material for performing an etch-stop function; and
a phase-change material positioned between the first electrode and the second electrode.

2. The memory cell of claim 1, wherein the phase-change material is positioned between the first layer and the first electrode.

3. The memory cell of claim 1, wherein the etch-stop material has a lower etch rate relative to the second layer.

4. A memory cell comprising:
a first electrode;
a second electrode including a first layer and a second layer, the first layer configured to perform an etch-stop function; and
a phase-change material between the first electrode and the second electrode,
wherein the first layer of the second electrode is for preventing over-etching or under-etching of the phase-change material.

5. The memory cell of claim 4, wherein a thickness of the first layer is less than a thickness of the second layer.

6. The memory cell of claim 4, wherein the phase-change material comprises at least one of Ge, Sb, Te, Ga, As, In, Se, and S.

7. The memory cell of claim 4, wherein the first layer comprises a material selected from the group consisting of TiN, TaN, and W.

8. The memory cell of claim 4, wherein the second layer comprises one of W and Al.

9. The memory cell of claim 4, wherein the memory cell is a pillar cell.

10. A memory cell comprising:
a first electrode;
a second electrode;
a phase-change material between the first electrode and the second electrode; and
means for stopping a first etch to prevent over-etching or under-etching of the phase-change material during fabrication of the memory cell.

11. The memory cell of claim 10, wherein the phase-change material comprises at least one of Ge, Sb, Te, Ga, As, In, Se, and S.

12. The memory cell of claim 10, wherein the second electrode comprises a first layer, the first layer comprising a material selected from the group consisting of TiN, TaN, and W.

13. The memory cell of claim 12, wherein the second electrode comprises a second layer, the second layer comprising one of W and Al.

14. The memory cell of claim 10, wherein the memory cell is a pillar cell.

15. A method for fabricating a memory cell, the method comprising:
providing a preprocessed wafer including a first electrode;
depositing a phase-change material over the preprocessed wafer;
depositing a first material over the phase-change material;
depositing a second material over the first material;
etching the second material with a first etch to form a first portion of a second electrode; and
etching the first material and the phase-change material with a second etch to form a second portion of the second electrode and a storage location.

16. The method of claim 15, wherein an etch rate of the first material is slower than an etch rate of the second material.

17. The method of claim 15, wherein depositing the phase-change material comprises depositing a phase-change material comprising at least one of Ge, Sb, Te, Ga, As, In, Se, and S.

18. The method of claim 15, wherein depositing the first material comprises depositing a material selected from the group consisting of TiN, TaN, and W.

19. The method of claim 15, wherein depositing the second material comprises depositing one of W and Al.

20. A method for fabricating a pillar memory cell, the method comprising:
providing a preprocessed wafer including a first electrode;
depositing a phase-change material over the preprocessed wafer;
depositing a first layer of a second electrode over the phase-change material;
depositing a second layer of the second electrode over the first layer, the second layer having a thickness greater than a thickness of the first layer;
etching the second layer with a first etch; and
etching the first layer and the phase-change material with a second etch.

21. The method of claim 20, wherein depositing the phase-change material comprises depositing a phase-change material comprising at least one of Ge, Sb, Te, Ga, As, In, Se, and S.

22. The method of claim 20, wherein depositing the first layer comprises depositing a material selected from the group consisting of TiN, TaN, and W.

23. The method of claim 20, wherein depositing the second layer comprises depositing one of W and Al.
